(19) United States
(12) Patent Application Publication
(10) Pub. No.: US 2013/0087099 A1
(43) Pub. Date: Apr. 11, 2013

(54) In-Situ Hydroxylation Apparatus

(71) Applicant: Kenric Choi, San Jose, CA (US)

(72) Inventor: Kenric Choi, San Jose, CA (US)

(73) Assignee: Applied Materials, Inc., Santa Clara, CA (US)

(21) Appl. No.: 13/364,910

(22) Filed: Feb. 2, 2012

Related U.S. Application Data
(60) Provisional application No. 61/543,642, filed on Oct. 5, 2011.

(51) Int. Cl. C23C 16/455; C23C 16/458; C23C 16/52

(52) U.S. Cl. 118/724; 118/728

(57) ABSTRACT

Described are apparatuses and methods for the hydroxylation of a substrate surface using ammonia and water vapor.

### CROSS-REFERENCE TO RELATED APPLICATIONS

This application claims the benefit under 35 U.S.C. §119(e) to U.S. Provisional Application No. 61/543,642, filed Oct. 5, 2011.

### FIELD

Embodiments of the present invention generally relate to apparatuses and methods for producing hydroxyl groups on the surface of a substrate.

### BACKGROUND

Deposition of thin films on a substrate surface is an important process in a variety of industries including semiconductor processing, diffusion barrier coatings and dielectrics for magnetic read/write heads. In the semiconductor industry, miniaturization can involve atomic level control of thin film deposition to produce conformal coatings on high aspect structures. One method for deposition of thin films with atomic layer control and conformal deposition is atomic layer deposition (ALD), which employs sequential, self-limiting surface reactions to form layers of precise thickness controlled at the Angstrom or monolayer level. Most ALD processes are based on binary reaction sequences which deposit a binary compound film. Each of the two surface reactions occurs sequentially, and because they are self-limiting, a thin film can be deposited with atomic level control. Because the surface reactions are sequential, the two gas phase reactants are not in contact, and possible gas phase reactions that may form and deposit particles are limited. The self-limiting nature of the surface reactions also allows the reaction to be driven to completion during every reaction cycle, resulting in films that are continuous and pinhole-free.

ALD has been used to deposit metals and metal compounds on substrate surfaces. Al₂O₃ deposition is an example of a typical ALD process illustrating the sequential and self-limiting reactions characteristic of ALD. Al₂O₃ ALD conventionally uses trimethylaluminum (TMA, often referred to as reaction “A” or the “A” precursor) and H₂O (often referred to as the “B” reaction or the “B” precursor). In step A of the binary reaction, hydroxyl surface species react with vapor phase TMA to produce surface-bound AlOAl(CH₃)₂ and CH₄ in the gas phase. This reaction is self-limited by the number of reactive sites on the surface. In step B of the binary reaction, AlCH₃ of the surface-bound compound reacts with vapor phase H₂O to produce AlOH bound to the surface and CH₄ in the gas phase. This reaction is self-limited by the finite number of available reactive sites on surface-bound AlOAl(CH₃)₂. Subsequent cycles of A and B, purging gas phase reaction products and unreacted vapor phase precursors between reactions and between reaction cycles, produces Al₂O₃ growth in an essentially linear fashion to obtain the desired film thickness.

However, many ALD reactions require the presence of reactive “handles” for the ALD precursors to react with the substrate surface. One way of adding such reactivity is by adding —OH (hydroxyl) groups to the substrate surface. One previously known method of hydroxylation involved submersing the substrate in a bath containing liquid ammonia and water. This process would make the interface layer surface —OH rich, but had the disadvantage of exposing the wafer to the atmosphere when the wafer is transferred from the bath to a process chamber for formation of the film. For some films such as high-κ dielectric films, for example, hafnium oxide, exposure to air degrades the hysteresis of the device incorporating the dielectric film. The mixture of ammonia and water forms ammonium hydroxide, which is a strong base that is caustic and degrades many metals. Accordingly, processes that involve mixture of ammonia and water have not been performed in process chambers due to the expected degradation of metal components.

Therefore, there is a need to provide methods to improve the available processes of hydroxylation of a substrate surface.

### SUMMARY OF THE INVENTION

One aspect of the current invention relates to an apparatus to hydroxylate a substrate surface. In one or more embodiments of this aspect, the apparatus comprises: a chamber body having a chamber wall, a chamber plate and a chamber lid, the chamber wall, chamber plate and chamber lid defining a chamber process area in which a substrate can be placed to hydroxylate a surface of the substrate; a wafer support disposed within the chamber process area, the wafer support preventing a substrate placed in the chamber process area from directly contacting the chamber plate; a lifting mechanism positioned within the process chamber that lowers the substrate on to and raises the substrate off the wafer support; and one or more injectors that deliver amine and hydroxide into the chamber process area to expose a substrate in the chamber to ammonia hydroxide to hydroxylate the substrate. According to one or more embodiments, the chamber body, wafer support, lifting mechanism and one or more injectors comprise materials resistant to degradation by ammonium hydroxide.

Certain embodiments provide the materials resistant to degradation by ammonium hydroxide comprise one or more of stainless steel, quartz and polytetrafluoroethylene. In a particular embodiment, the materials resistant to degradation by ammonium hydroxide comprise stainless steel.

In one or more embodiments, the lifting mechanism comprises at least a peripheral frame. According to one or more embodiments, the peripheral frame is engaged with a motor that raises and lowers the frame. Certain embodiments provide the peripheral frame at least partially peripherally surrounds a substrate. In further embodiments, the frame comprises a plurality of inwardly-directed fingers spaced about the peripheral frame. Still further embodiments provide the lifting mechanism further comprises a plurality of ceramic standoffs embedded into the frame that enable point contact of the frame with the substrate. According to a particular embodiment, the ceramic comprises silicon nitride.

According to one or more embodiments, the wafer support comprises a plurality of ceramic balls embedded in the chamber plate that enable a plurality of point contacts with the substrate. In certain embodiments, the ceramic comprises silicon nitride.

In one or more embodiments, the apparatus further comprises a heating system that maintains temperature adjacent to the chamber lid and chamber wall such that ammonia and water do not react adjacent to the chamber lid and chamber wall and ammonia and water react adjacent to a substrate on the wafer support. In further embodiments, the apparatus comprises a heating element adjacent to the chamber lid and chamber wall that elevates the temperature adjacent to the chamber lid and chamber wall and a thermal element that raises or lowers the temperature adjacent to the chamber plate.

Another aspect of the invention provides an apparatus to hydroxylate a substrate surface, the apparatus comprising: a chamber body having a chamber wall, a chamber plate and a chamber lid, the chamber wall, chamber plate and chamber lid defining a chamber process area in which a substrate can be placed to hydroxylate a surface of the substrate; a wafer support disposed within the chamber process area, the wafer support preventing a substrate placed in the chamber process area from directly contacting the chamber plate; a lifting mechanism positioned within the process chamber that lowers the substrate on to and raises the substrate off the wafer support; one or more injectors that deliver amine and hydroxide into the chamber process area to expose a substrate in the chamber to ammonia hydroxide to hydroxylate the substrate, wherein the chamber body, wafer support, lifting mechanism and one or more injectors comprise materials resistant to degradation by ammonium hydroxide; and a transfer valve disposed in the chamber wall that permits a substrate to be loaded into the process area and out of the process chamber to a transfer chamber adjacent the transfer valve.

In one or more embodiments of this aspect, the transfer valve comprises a purge gas injector that flows purge gas when the transfer valve is in an open position. According to one or more embodiments, the lifting mechanism comprises a peripheral frame engaged with a motor that raises and lowers the frame, and a plurality of ceramic standoffs embedded into the frame that enable point contact of the frame with the substrate

Yet another aspect provides an apparatus to hydroxylate a substrate surface, the apparatus comprising: a chamber body having a chamber wall, a chamber plate and a chamber lid, the chamber wall, chamber plate and chamber lid defining a chamber process area in which a substrate can be placed to hydroxylate a surface of the substrate when processed in the chamber; a wafer support disposed within the chamber process area, the wafer support preventing a substrate placed in the chamber process area from directly contacting the chamber plate; a lifting mechanism positioned within the process chamber that lowers the substrate on to and raises the substrate off the wafer support; one or more injectors that deliver amine and hydroxide into the chamber process area to expose a substrate in the chamber to ammonium hydroxide to hydroxylate the substrate; and a chamber controller that regulates flow of amine and hydroxide in the chamber and controls the temperature in the chamber to provide a desired relative humidity in the process area to hydroxylate a surface of a substrate when processed in the chamber.

One or more embodiments of this aspect provide that the chamber body, wafer support, lifting mechanism and one or more injectors comprise materials resistant to degradation by ammonium hydroxide. In certain embodiments, the materials resistant degradation by ammonium hydroxide comprise one or more of stainless steel, quartz and polytetrafluoroethylene.

According to one or more embodiments, the apparatus further comprises a heating system that maintains temperature adjacent to the chamber lid and chamber wall such that ammonia and water do not react adjacent to the chamber lid and chamber wall and ammonia and water react adjacent to a substrate on the wafer support.

The foregoing has outlined rather broadly certain features and technical advantages of the present invention. It should be appreciated by those skilled in the art that the specific embodiments disclosed may be readily utilized as a basis for modifying or designing other structures or processes within the scope present invention. It should also be realized by those skilled in the art that such equivalent constructions do not depart from the spirit and scope of the invention as set forth in the appended claims.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A illustrates a side cross-sectional view of the process area of an apparatus in accordance with one or more embodiments of the invention;

FIG. 1B illustrates a top cross-sectional view of the process area of an apparatus in accordance with one or more embodiments of the invention;

FIG. 2 illustrates a schematic of a system in accordance with one or more embodiments of the invention; and

FIG. 3 illustrates a schematic of a cluster tool system in accordance with one or more embodiments of invention.

### DETAILED DESCRIPTION

Various embodiments described herein provide methods and apparatuses for the hydroxylation of a substrate surface without exposure to air, thereby preventing degradation of hysteresis of devices containing dielectric films. Embodiments of the invention pertain to the provision of processes and apparatus that can be performed in a process area of chamber that avoid exposure of the substrate to ambient air.

As used herein, a “substrate surface,” refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Barrier layers, metals or metal nitrides on a substrate surface include titanium, titanium nitride, tungsten nitride, tantalum and tantalum nitride, aluminum, copper, or any other conductor or conductive or non-conductive barrier layer useful for device fabrication. Substrates may have various dimensions, such as 200 mm or 300 mm diameter wafers, as well as, rectangular or square panes. Substrates on which embodiments of the invention may be useful include, but are not limited to semiconductor wafers, such as crystalline silicon (e.g., Si<100> or Si<111>), silicon oxide, strained silicon, silicon germanium, doped or undoped polysilicon, doped or undoped silicon wafers, III-V materials such as GaAs, GaN, InP, etc. and patterned or non-patterned wafers. Substrates may be exposed to a pretreatment process to polish, etch, reduce, oxidize, hydroxylate, anneal and/or bake the substrate surface.

Accordingly, one aspect of the invention relates to a method of preparing a substrate for formation of a dielectric film on a surface of the substrate, the method comprising disposing a substrate in a process chamber and flowing a hydroxide, such as water vapor, and an amine, such as ammonia, into the process chamber. The water vapor and ammonia are flowed such that a surface of the substrate is simultaneously exposed to water vapor and ammonia. This method is performed under vacuum conditions, i.e. under reduced pressure and without exposing the substrate to ambient air. According to one or more embodiments, inert gases such as nitrogen may be present in the hydroxylation chamber.

Although specific reference is made to water vapor and ammonia, it will be understood that the invention encompasses the use of other hydroxide and amine sources. For example, suitable hydroxides include water and hydrogen peroxide. Example of suitable amines include ammonia, pyridine, hydrazine, alkyl amines and aryl amines.

The water vapor and ammonia react at the surface of the substrate to provide ammonium hydroxide, which then reacts with the surface of the substrate to provide a hydroxylated substrate. In specific embodiments, the substrate surface is not halogenated prior to hydroxylation. According to one or more embodiments, the only functionality added to the surface of the substrate or film is hydroxyl functionality.

According to one or more embodiments, the substrate is subjected to further processing after hydroxylating the surface. This further processing can be performed in the same chamber as the hydroxylation chamber, or can be performed in one or more separate processing chambers. In one embodiment, the hydroxylated substrate is moved from the hydroxylation chamber to a separate, second chamber for further processing. The hydroxylated substrate can be moved directly from the hydroxylation chamber to the separate processing chamber, or it can be moved from the hydroxylation chamber to one or more transfer chambers, and then moved to the desired separate processing chamber.

According to one or more embodiments, the hydroxylated substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants after hydroxylating the surface of the substrate. According to one or more embodiments, a purge gas is injected at the exit of the hydroxylation chamber to prevent reactants from moving from the hydroxylation chamber to the transfer chamber and/or processing chamber. Thus, the flow of inert gas forms a curtain at the exit of the chamber.

Other processing chambers can include, but are not limited to, deposition chambers and etching chambers. According to one or more embodiments, a film is deposited on the hydroxylated substrate by a deposition process, such as chemical vapor deposition (CVD) or atomic layer deposition (ALD). In a particular embodiment, a film is deposited on the substrate via an atomic layer deposition process.

In one or more embodiments, a film having a high dielectric constant (κ) is deposited on the hydroxylated substrate. Materials that may be used to make high-κ gate dielectrics include, but are not limited to: hafnium oxide, lanthanum oxide, lanthanum aluminum oxide, zirconium oxide, zirconium silicon oxide, titanium oxide, tantalum oxide, yttrium oxide, and aluminum oxide. In some embodiments, the high-κ dielectric film comprises hafnium. Thus, an aspect of the invention pertains to a method of forming a dielectric film on a surface of the substrate. The method of forming a dielectric film can include controlling flow of ammonia and water vapor into a process area of a hydroxylation chamber to simultaneously expose the surface of the substrate to the water vapor and the ammonia to provide a hydroxylated substrate surface. The method can further include controlling pressure within the process chamber and moving the hydroxylated substrate from the hydroxylation chamber to a transfer chamber and to a deposition chamber under load lock conditions. Finally, the method includes depositing a film, for example, a dielectric film on the hydroxylated substrate.

According to one or more embodiments of this aspect, the method further comprises controlling the temperature distribution in the process area such that ammonia and water react adjacent to the substrate, but ammonia and water do not react in other portions of the process area, such as adjacent to the chamber lid or chamber wall. In certain embodiments, the film is deposited via an atomic layer deposition process.

Thus, another aspect of the invention pertains to an apparatus for the hydroxylation of a substrate to perform a process according to any of the embodiments described above. One embodiment relates to an apparatus comprising a chamber body, wafer support, a lifting mechanism and one or more injectors. This apparatus will provide a supply of water vapor and ammonia to the substrate surface, which will react to form ammonium hydroxide, which in turn hydroxylates the surface of the substrate.

As the water vapor and ammonia will react to form ammonium hydroxide, the chamber process area will have a caustic environment. Accordingly, all components in the wetted path should comprise materials resistant to degradation by ammonium hydroxide. Thus, typical materials employed in semiconductor processing chambers, such as aluminum, are not suitable for components that will be exposed to the caustic environment. According to one or more embodiments, the chamber body, wafer support and one or more injectors comprise materials resistant to degradation by ammonium hydroxide. In further embodiments, the lifting mechanism also comprises a material resistant to degradation by ammonium hydroxide.

Many materials can be used that will provide the desired resistance to ammonium hydroxide. For example, stainless steel, quartz and polytetrafluoro-ethylene could be used for various components in the apparatus. In a particular embodiment, one or more components of the apparatus components comprise stainless steel.

The chamber body has a chamber wall, a chamber plate and a chamber lid. The chamber wall, chamber plate and chamber lid define a chamber process area, which is the area in which the hydroxylation reaction takes place. The one or more injectors disperse ammonia and water vapor into the chamber process area, which react to form ammonium hydroxide. The ammonium hydroxide then reacts with the surface of the substrate to provide a hydroxylated substrate.

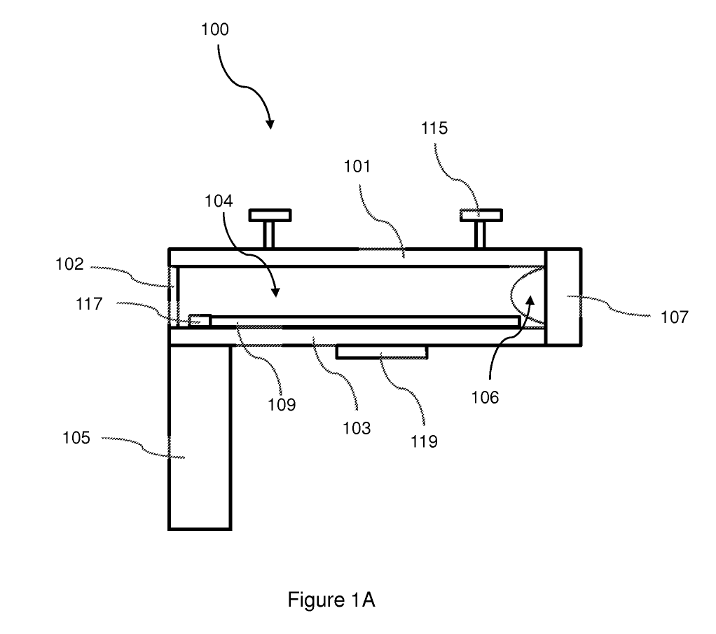

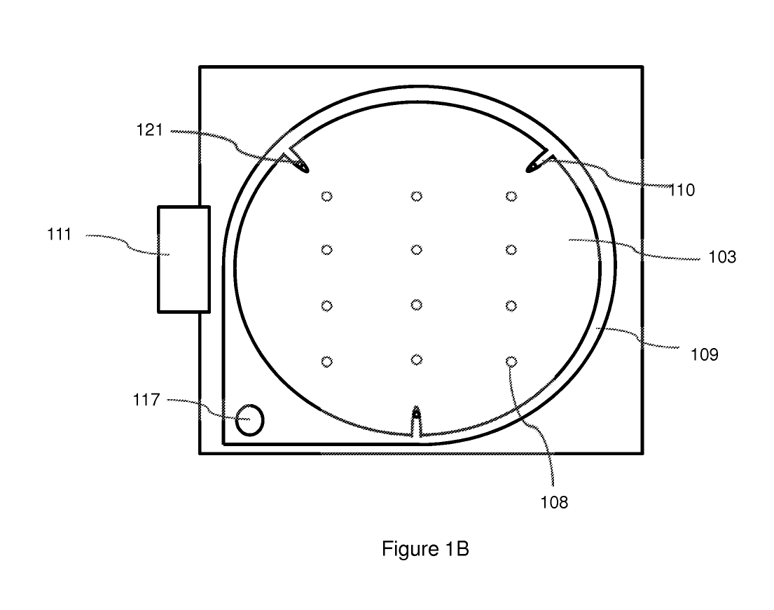

FIG. 1A illustrates a side cross-sectional view of an embodiment of chamber body 100 in accordance with this aspect of the invention. Chamber body 100 comprises chamber lid 101, chamber wall 102 and chamber plate 103 define a chamber process area 104. The apparatus shown in FIGS. 1A and 1B shows the chamber wall 102 as a single wall defining a process area that is generally circular in cross-section. However, it will be understood that the process area 104 can be any suitable shape for processing substrates, and the chamber wall 102 defining the process area can comprise multiple discrete wall elements. The chamber lid 101 forms the top boundary of the process area 104. The chamber lid 101 can be opened or removable to facilitate cleaning and maintenance of the process area. In the embodiment shown the chamber lid 101 includes handles 115 for lifting the chamber lid 101 from the chamber wall 101. The chamber lid 101 can be held in place by any suitable means such as set screws, clamps, etc. In other embodiments, the chamber lid can be mounted to the chamber wall 101 by a hinge (not shown), or the lid may be movably associated with the chamber wall 101 such as by a vertical or horizontal retraction mechanism (not shown). Lifting mechanism 105 raises and lowers a substrate, and is used to move the substrate into and out of the chamber process area 104 through opening 106. Slit valve insert 107 can connect the apparatus to another chamber. Slit valve insert 107 may comprise injectors for a purge gas to prevent reactant gases from leaving the chamber process area 104 when the substrate is moved in and out of the apparatus.

The apparatus also includes a peripheral frame 109, which is best shown in FIG. 1B. The peripheral frame 109 is engaged with a lifting mechanism 105, which can be a servo motor or any other suitable device for moving the peripheral frame 109 up and down to raise and lower a substrate in the process area 104. In the embodiment shown, the lifting mechanism includes a shaft 117 in contact with a portion of the peripheral frame 109.

FIG. 1B illustrates a top cross-sectional view of the process area. Ceramic balls 108 are affixed to the chamber plate 103. The ceramic balls can be affixed to the plate by a variety of ways such as by bonding, adhesive, press-fitting, etc. In the embodiment shown, the ceramic balls are press fit into holes in the chamber plate 103. The ceramic balls 108 provide an offset for a substrate loaded into the process area 104 and onto the chamber plate 103. Thus, a substrate that has been loaded into the process area 104 and resting on the ceramic balls 108 will not come into direct contact with chamber plate 103. This facilitates loading and removal of a substrate from the process area 104. As discussed above, the peripheral frame 109 is operably engaged with the lifting mechanism 105 by shaft 117 to allow the peripheral frame 109 to lower a substrate onto ceramic balls 108, Fingers 110 are spaced about the peripheral of frame 109, and point inwardly from frame 109. Injector 111 disperses ammonia and water vapor across the surface of the substrate while it rests on the ceramic balls 108.

In the embodiment shown, the ceramic balls function as a wafer support within the chamber process area. This wafer support elevates a substrate within the process area above the chamber plate, and a substrate in the chamber process area rests upon the wafer support. This prevents direct contact between the back of the substrate and the chamber plate. Direct contact between the substrate and the chamber plate can result in backside metal contamination of the substrate from the chamber plate. In a particular embodiment, there is no direct contact between the substrate and the chamber plate. It will be understood that the wafer support is not limited to ceramic balls. In other embodiments, the wafer support can comprise lift pins, standoffs, or any other suitable element.

Thus, the wafer support may comprise any configuration that generally minimizes contact between the chamber plate and the substrate. In one or more embodiments, the wafer support includes a ceramic support such as a plurality of ceramic balls. In one or more embodiments, these ceramic balls are embedded in the chamber plate. The substrate rests on the top of these balls and does not make contact with the chamber plate below. Thus, only a plurality of point contacts are made with the substrate, instead of the substrate laying directly on the top of the chamber plate. According to a certain embodiment, the ceramic support comprises silicon nitride.

According to one or more embodiments, the apparatus further comprises a heating system (not shown) to maintain temperature adjacent to the chamber wall and/or chamber lid such that ammonia and water do not react adjacent to the chamber wall and/or chamber lid, but instead will react adjacent to a substrate on the wafer support. In certain embodiments, this heating system heats the chamber wall and/or chamber lid to help prevent the reactants from reacting with the wall 102 or lid 101. Thus, the chamber wall and/or chamber lid may be adjacent to with a heating element. For example the chamber wall 102 can have a resistive heating element embedded therein to heat the chamber wall 102. Alternatively, or in addition to resistive heating elements, radiant heating elements such as lamps can be provided inside or adjacent the process area 104 to heat chamber wall 102 and lid 101.

Certain embodiments provide that the chamber plate 103 is heated or cooled. The temperature of the chamber plate 103 can be adjusted to achieve the desired relative humidity at the surface of the substrate. According to a specific embodiment, the temperature of the chamber process area 104 is maintained in the range of about 20° C. to about 60° C. In one or more embodiments, the temperature at the substrate surface is at or below about 25° C. to facilitate hydroxylation of the substrate. Thus, certain embodiments provide that the chamber plate and/or wafer support are adjacent to a thermal element 119 to raise and lower the temperature adjacent to the chamber plate to cause a local change in temperature at the surface of the substrate to be hydroxylated. The thermal element 119 can any suitable temperature altering device and can be positioned in various locations adjacent to or within the chamber. Suitable examples of thermal elements 119 include, but are not limited to, radiative heaters (e.g., lamps and lasers), resistive heaters, liquid controlled heat exchangers and cooling and heating plates. Cooling and heating plates can include one or more fluid channels through which a liquid or gas flows to cool or heat the plate. In a specific embodiment, the chamber plate is in thermal contact with a cooling element.

One or more injectors 111 are configured to be connected to an ammonia supply and a water vapor supply (not shown). The ammonia and water may be dispersed from the same injector, or multiple injectors may be used to prevent mixing before reaching the chamber process area. Any appropriate flow configuration may be used for dispersing the ammonia and water vapor, including cross flow or top-down flow. The injectors 111 may comprise any means for dispersing the reactants into the chamber process area, including a showerhead or baffle plate.

The lifting mechanism 105 coupled to the peripheral frame 109 is used to lower and raise the substrate from the wafer support, and can utilize any mechanical means to do so. In addition to raising and lowering the substrate from the wafer support, the lifting mechanism 105 may also carry the substrate in and out of the chamber process area 104 through an opening in the chamber 106. According to one or more embodiments, the lifting mechanism 105 comprises the peripheral frame 109, and the substrate can rest on the peripheral frame 109 as it raises or lowers the substrate. In certain embodiments, the peripheral frame 109 is operatively engaged with a motor to raise and lower the frame.

According the certain embodiments, the peripheral frame 109 at least partially peripherally surrounds a substrate. In the embodiment shown, the peripheral frame is a portion of a circle. In the embodiment shown the peripheral frame is about 270 degrees, however, the invention is not limited to this configuration, and the peripheral frame 109 can be a full circle, a semi-circle (180 degrees) or any other configuration that is suitable for raising and lowering a substrate such as a semiconductor wafer. In certain embodiments, the peripheral frame 109 comprises a plurality of inwardly-directed fingers 110 spaced about the peripheral frame. In the embodiment shown in FIG. 1B, three fingers 110 are shown. However, more or fewer fingers 110 can be provided.

In one or more embodiments, the lifting mechanism may contain a standoff that minimizes contact between the substrate and the peripheral frame 109. In certain embodiments, similar to the chamber plate 103, the standoff may comprise a plurality of ceramic standoffs 121 protruding from an upper surface of the peripheral frame 109 to enable point contact with the substrate. In a particular embodiment, the ceramic standoffs 121 are embedded in the plurality of the inwardly-directed fingers 110. In specific embodiments, the ceramic standoffs 121 comprise silicon nitride.

The apparatus may also comprise a transfer valve 107 located in a side wall of the chamber. In one or more embodiments, the transfer valve 107 is a slit valve. The slit valve 107 can be an opening in which the substrate may enter and exit the hydroxylation chamber process area 104. The slit valve 107 can include a door (not shown) and may be configured to connect to another chamber, such as a transfer chamber or adjacent process chamber. According to one or more embodiments, the slit valve insert comprises a purge gas injector (not shown), which is used to prevent reactant gases from exiting the hydroxylation chamber and entering an adjacent chamber when the slit valve is in an open position, and to prevent ambient air from entering the process area 104. Any suitable inert gas may be used as a purge gas, including nitrogen.

Another aspect of the invention relates to a system to hydroxylate a substrate surface. According to one or more embodiments, this system comprises a chamber body 100 including a substrate support, an ammonia supply, a water vapor supply, and one or more injectors as described above with respect to FIGS. 1A and 1B. In certain embodiments, the system may also comprise a pressure control valve to control pressure in the chamber process area. The system may further comprise a control system that regulates the pressure in the chamber process area, as well as the flow of ammonia and water vapor into the chamber body. The control system regulates the pressure and flow of reactants such that the surface of the substrate is simultaneously exposed to the water vapor and the ammonia to provide a hydroxylated substrate surface. In one or more embodiments, the system further comprises a transfer valve to move a substrate from the process area to a transfer chamber under controlled pressure to prevent exposure of the hydroxylated substrate to ambient air.

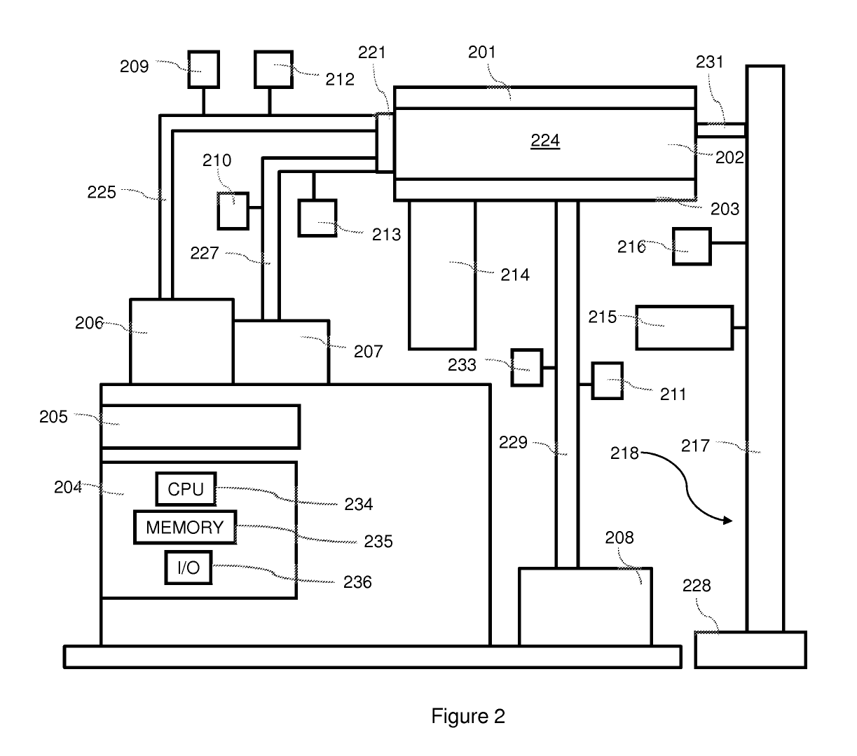

FIG. 2 illustrates one embodiment in accordance with this aspect of the invention. Chamber body includes a chamber lid 201, chamber wall 202, and a chamber plate 203. Chamber lid 201, chamber wall 202 and chamber plate 203 define a chamber process area 224 where the hydroxylation reaction occurs on a substrate surface. Lifting mechanism 214 raises and lowers the substrate so that the substrate can be moved in and out of the chamber process area with a robot blade or other suitable transfer mechanism.

Ammonia gas is provided by ammonia supply 206, which is delivered into the process area 224 via ammonia conduit 225, which can be any suitable conduit such as piping or channel to deliver ammonia at an appropriate flow rate to the process area 224 through injector 221. The ammonia supply can be a cylinder of ammonia gas or an ammonia generation system to generate ammonia gas. The flow of ammonia gas to the chamber is regulated by ammonia valve 209 and ammonia flow controller 212, which can communicate with chamber controller 204. The flow controller 212 can be a mass flow or volume flow controller. Water vapor is provided by water vapor supply 207 delivered to the process area 224 via conduit 227 through the injector 221.The flow of water vapor is regulated by water valve 210 and water flow controller 213, which can be a mass flow or volume flow controller. Valve 210 and flow controller 213 can be in communication with chamber controller 204. As shown in FIG. 2, the ammonia and water vapor may be delivered to the chamber separately via separate conduits 225 and 227. However, it is within the scope of the invention to mix the ammonia and water vapor prior to introducing the gases into the chamber, and deliver them in a single conduit.

An inert gas supply 208 can be used to provide an inert gas as a purge gas via inert gas conduit 229 to remove reactants and/or byproducts from the chamber body via the exhaust system 218. In addition, the inert gas can be used as a carrier gas to deliver reactants into the chamber by mixing the inert gas with one or both the ammonia supply or the water vapor supply. If the inert gas is to be used as a carrier gas, the inert gas conduit would include appropriate interconnects (not shown) to connect inert gas conduit 229 with one or both of ammonia gas conduit 225 and/or water vapor conduit 227. Appropriate interconnects would include valves and/or flow controllers (not shown) that would be in communication with chamber controller 204. Inert gas valve 211 regulates the flow of inert gas to the chamber body. A flow controller 233 may also be used to regulate the flow of inert gas into the chamber

A temperature controller 205 may control the various heating and cooling elements of the system, such as heating elements for the water vapor system 207, chamber lid 201 and chamber wall 202, or the heating and/or cooling elements for the chamber plate 203.

Exhaust system 218 removes gases from the chamber body. A pump 228 in flow communication with exhaust line 217 connected to the chamber via exhaust conduit 231 removes excess reactants and byproducts of the hydroxylation process from the process area 224 when the hydroxylation process is complete. An isolation valve 216 can be used to isolate the chamber body from the pump 228. A throttle valve 215 can be used to regulate the pressure in the chamber body to achieve the desired relative humidity in the process area 224. Thus, it will be understood that the pressure and/or the temperature can be regulated or modified to control the partial pressure of water to provide the desired relative humidity in the process area and to hydroxylate the substrate. Relative humidity refers to the percentile ratio of water partial pressure over water saturation pressure at a specific temperature. In specific embodiments, the vapor pressure of the water is 20% of the saturated vapor pressure at the temperature of the substrate. In other specific embodiments, the saturated vapor pressure of the water is 40%, 60% or 80% the saturated vapor pressure at the temperature of the substrate.

The chamber body, injectors, wafer support, and lifting mechanism may have any of the features previously described for the apparatus for hydroxylation.

As described above, the ammonia and water react to form ammonium hydroxide, which is a caustic environment. Thus, according to certain embodiments, the components exposed to ammonium hydroxide should be comprised of materials resistant to degradation. Such materials include, but are not limited to, stainless steel, quartz and polytetrafluoroethylene.

The water vapor supply provides the water vapor to be used in the hydroxylation, and may comprise any system capable of delivering water vapor to the chamber process area suitable to effect a hydroxylation reaction on a substrate surface. The water vapor may either be generated by a water vapor generation system or may be generated at another source and provided to the system. According to certain embodiments, the water vapor is produced by a water ampoule that is bubbled or vapor drawn. Thus, certain embodiments provide the water vapor supply comprises a liquid water source and a gas source connected to the water source to bubble gas through the water to form water vapor.

Alternatively, the water vapor can be produced by atomizing or vaporizing water. In certain embodiments, the system comprises a container holding water and a water atomizer such as a nebulizer or nozzle relying on the Venturi effect. In other embodiments, the water vapor supply comprises a liquid water source and a heating element such as one or more Peltier devices controlled a Peltier controller and in communication with the chamber controller 204. In yet another embodiment, the water vapor can be generated by a unit using hydrogen and oxygen gases.

In one or more embodiments, various elements of the system such as the ammonia flow controller 212, the water vapor flow controller 213, the temperature controller 205 and the Peltier controller are controlled by the chamber controller 204, which provides I/O control of the system. Thus, the chamber controller 204 can include a CPU 234, a memory 235 and an I/O 236 in wired or wireless communication with the various controllers. The CPU 234 sends and receives signals to the ammonia flow controller 212 and the water vapor controller 213 to control the flow of ammonia and water vapor to the injector 221. The CPU 234 also sends and receives signals to the throttle valve 215 to control pressure in the chamber process area so that the throttle valve 215 operates as a pressure control valve for the system. The CPU 234 can also be in communication with the isolation valve 216 and pump 228 to further control the flow of exhaust from the chamber.

The CPU may be one of any forms of a computer processor that can be used in an industrial setting for controlling various chambers and sub-processors. Thus, the CPU can be coupled to the memory 235 which may be one or more of readily available memory such as random access memory (RAM), read only memory (ROM), flash memory, compact disc, floppy disk, hard disk, or any other form of local or remote digital storage. Support circuits (not shown) can be coupled to the CPU to support the CPU in a conventional manner. These circuits include cache, power supplies, clock circuits, input/output circuitry, subsystems, and the like. The CPU 234 and the memory 235 are coupled to an appropriate I/O circuit 236 to communicate with the various controllers of the system.

The control system may further a computer-readable medium having a set of machine-executable instructions. These instructions may be such that, when executed by the CPU, cause the system to perform any of the methods previously described. In one embodiment, the instructions relate to a method comprising simultaneously exposing a surface of the substrate to water vapor and ammonia to provide a hydroxylated substrate. In another embodiment, the instructions relate to a method comprising: simultaneously exposing a surface of the substrate to water vapor and ammonia to provide a hydroxylated substrate; moving the hydroxylated substrate from the hydroxylation chamber to the transfer chamber; moving the hydroxylated substrate from the transfer chamber to a deposition chamber; and depositing a film on the hydroxylated substrate.

The hydroxylation system may further comprise other chambers in addition to the hydroxylation chamber. These chambers can include transfer chambers and additional processing chambers, such as deposition chambers and etching chambers. These chambers may be interconnected in a “cluster tool system.”

Generally, a cluster tool is a modular system comprising multiple chambers which perform various functions including substrate center-finding and orientation, degassing, annealing, deposition and/or etching. According to an embodiment of the present invention, a cluster tool includes at least a hydroxylation chamber configured to perform the inventive hydroxylation processes. The multiple chambers of the cluster tool are mounted to a central transfer chamber which houses a robot adapted to shuttle substrates between the chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present invention are the Centura® and the Endura®, both available from Applied Materials, Inc., of Santa Clara, Calif. The details of one such staged-vacuum substrate processing system are disclosed in U.S. Pat. No. 5,186,718, entitled “Staged-Vacuum Wafer Processing System and Method,” Tepman et al., issued on Feb. 16, 1993. However, the exact arrangement and combination of chambers may be altered for purposes of performing specific steps of a process as described herein.

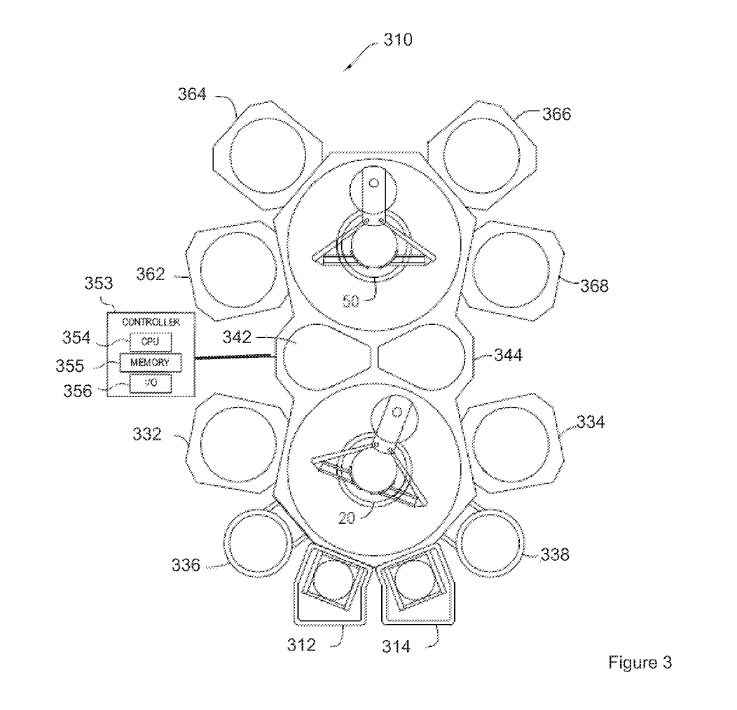

FIG. 3 shows an example of a cluster tool or multi-chamber processing system 310 that can be used in conjunction with an aspect of the invention. The processing system 310 can include one or more load lock chambers 312, 314 for transferring substrates into and out of the system 310. Typically, since the system 310 is under vacuum, and the load lock chambers 312, 314 may “pump down” substrates introduced into the system 310. A first robot 320 may transfer the substrates between the load lock chambers 312, 314, and a first set of one or more substrate processing chambers 332, 334, 336, 338. Each processing chamber 332, 334, 336, 338, may be configured to perform a number of substrate processing operations. For example, processing chamber 332 can be an etch processor designed to practice an etch process, and processing chamber 334 can be a deposition reaction chamber for performing ALD or CVD, or a rapid thermal processing (RTP) or RadOx® chamber designed to form a thermal oxide layer on a susbtrate. Processing chambers 336, 338 may also be configured to further provide, for example, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes.

The first robot 320 can also transfer substrates to/from one or more transfer chambers 342, 344. The transfer chambers 342, 344 can be used to maintain vacuum conditions while allowing substrates to be transferred within the system 310. A second robot 350 can transfer the substrates between the transfer chambers 342, 344 and a second set of one or more processing chambers 362, 364, 366, 368. Similar to processing chambers 332, 334, 336, 338, the processing chambers 362, 364, 366, 368 can be configured to perform a variety of substrate processing operations, including etch processes, in addition to cyclical layer deposition (CLD), atomic layer deposition (ALD), chemical vapor deposition (CVD), physical vapor deposition (PVD), epitaxial deposition, etch, pre-clean, chemical clean, thermal treatment such as RTP/RadOx®, plasma nitridation, degas, and orientation. Any of the substrate processing chambers 332, 334, 336, 338, 362, 364, 366, 368 may be removed from the system 310 if not needed.

By carrying out this process in a chamber on a cluster tool, surface contamination of the substrate with atmospheric impurities is avoided and at the same time maintain the benefits of increased nucleation from a wet chemical treatment.

Applied Materials, Inc. of Santa Clara, Calif. offers a substrate processing chamber which includes a process called RadOx® to form thin silicon dioxide layers for CMOS transistor gates. The RadOx® process heats the substrate with lamps and injects hydrogen and oxygen into a process chamber. These gases form radicals when they strike the surface of the substrate. The radicals are more reactive than neutral species, providing a faster layer growth rate than would be available with steam processes known as In Situ Steam Generated (ISSG) oxide growth.

Suitable etch or clean chambers can be configured for wet or dry etch, reactive ion etch (RIE), or the like. Exemplary etch chambers include the SICONI™ Producer®, or Carina™ chambers, also available from Applied Materials, Inc. of Santa Clara, Calif. One non-limiting, exemplary dry etch process may include ammonia or (NH₃) or nitrogen trifluoride (NF₃) gas, or an anhydrous hydrogen fluoride (HF) gas mixture with a remote plasma, which condenses on SiO₂ at low temperatures (e.g., .about 30° C.) and reacts to form a compound which can be sublimated at moderate temperature (e.g., >100° C.) to etch SiO₂. Such an exemplary etch process can diminish over time and eventually saturate to a point where no further etching occurs unless portions of the compound are removed (for example, by the sublimation process described above). The etch process can be controlled using the above mechanism and/or by a timed etch process (e.g., etching for a predetermined period of time). Exemplary wet etch processes may include hydrogen fluoride (HF) or the like. Exemplary plasma or remote plasma etch processes may include one or more etchants such as carbon tetrafluoride (CF₄), trifluoromethane (CHF₃), sulfur hexafluoride (SF₆), hydrogen (H₂), or the like, and may be performed with or without a heating chuck.

In specific embodiments, a process is performed including a first step in which the robot 320 moves a substrate from one of the load lock chambers 312, 314 to a dry etch or cleaning chamber, for example, a SICONI™ chamber. After the dry etching or cleaning process, the substrate can be moved in a second step back into a load lock chamber 312, 314 or directly transferred to a rapid thermal processing chamber or RadOx® chamber for thermal treatment. Thereafter, in a third step, the robot 320 can move the substrate to one of the load lock chambers 312, 314 or directly to a hydroxylation chamber. Alternatively, in the third step, the substrate can be moved to a dry clean or etch chamber after the RTP or RadOx® chamber, or to a deposition chamber to form a medium-K dielectric. After processing in the hydroxylation chamber, RTP/RadOx® chamber or deposition of a medium K dielectric in the third step, a fourth step can involve deposition of a medium K dielectric or a high K dielectric. The fifth step can include deposition of a high K dielectric, or plasma nitridation of a high K dielectric formed in the fourth step, or RTP, or hydroxylation. Sixth and seventh steps can include processing in RTP/RadOx® and plasma nitridation, or formation of additional dielectric layers such as a medium K dielectric or high K dielectric.

In a specific embodiment of process performed in a cluster tool, the first step involves a dry etch/clean, the second step includes processing in an RTP chamber, the third step includes processing in a dry etch/clean chamber, a fourth step involves processing in a hydroxylation chamber as described herein, and a fifth step involves deposition of a high-K dielectric.

Examples of suitable high K dielectric materials include hafnium oxide, lanthanum oxide, lanthanum aluminum oxide, zirconium oxide, zirconium silicon oxide, titanium oxide, tantalum oxide, yttrium oxide, and aluminum oxide. Medium K dielectrics can be provided by doping the high K dielectrics with elements such as silicon and/or germanium.354

Controller 353 may be one of any form of general-purpose data processing system that can be used in an industrial setting for controlling the various subprocessors and subcontrollers. Generally, controller 353 includes a central processing unit (CPU) 354 in communication with memory 355 and input/output (I/O) circuitry 356, among other common components.

Reference throughout this specification to “one embodiment,” “certain embodiments,” “one or more embodiments” or “an embodiment” means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment” in various places throughout this specification are not necessarily referring to the same embodiment of the invention. Furthermore, the particular features, structures, materials, or characteristics may be combined in any suitable manner in one or more embodiments. The order of description of the above method should not be considered limiting, and methods may use the described operations out of order or with omissions or additions.

It is to be understood that the above description is intended to be illustrative, and not restrictive. Many other embodiments will be apparent to those of ordinary skill in the art upon reviewing the above description. The scope of the invention should, therefore, be determined with reference to the appended claims, along with the full scope of equivalents to which such claims are entitled.

What is claimed is:

1. An apparatus to hydroxylate a substrate surface, the apparatus comprising:
a chamber body having a chamber wall, a chamber plate and a chamber lid, the chamber wall, chamber plate and chamber lid defining a chamber process area;
a wafer support disposed within the chamber process area;
a lifting mechanism positioned within the process chamber that lowers the substrate on to and raises the substrate off the wafer support; and
one or more injectors that deliver amine and hydroxide to the chamber process area,
wherein the chamber body, wafer support, lifting mechanism and one or more injectors comprise materials resistant to degradation by ammonium hydroxide.

2. The apparatus of claim 1, wherein the materials resistant to degradation by ammonium hydroxide comprise one or more of stainless steel, quartz and polytetrafluoroethylene.

3. The apparatus of claim 1, wherein the materials resistant to degradation by ammonium hydroxide comprise stainless steel.

4. The apparatus of claim 1, wherein the lifting mechanism comprises at least a peripheral frame.

5. The apparatus of claim 4, wherein the peripheral frame is engaged with a motor that raises and lowers the frame.

6. The apparatus of claim 5, wherein the peripheral frame at least partially peripherally surrounds a substrate.

7. The apparatus of claim 6, wherein the frame comprises a plurality of inwardly-directed fingers spaced about the peripheral frame.

8. The apparatus of claim 7, wherein the lifting mechanism further comprises a plurality of ceramic standoffs embedded into the frame that enable point contact of the frame with the substrate.

9. The apparatus of claim 8, wherein the ceramic comprises silicon nitride.

10. The apparatus of claim 1, wherein the wafer support comprises a plurality of ceramic balls embedded in the chamber plate that enable a plurality of point contacts with the substrate.

11. The apparatus of claim 10, wherein the ceramic comprises silicon nitride.

12. The apparatus of claim 1, wherein the apparatus further comprises a heating system that maintains temperature adjacent to the chamber lid and chamber wall such that ammonia and water do not react adjacent to the chamber lid and chamber wall and ammonia and water react adjacent to a substrate on the wafer support.

13. The apparatus of claim 12, wherein the apparatus further comprises a heating element adjacent to the chamber lid and chamber wall that elevates the temperature adjacent to the chamber lid and chamber wall and a thermal element that raises or lowers the temperature adjacent to the chamber plate.

14. An apparatus to hydroxylate a substrate surface, the apparatus comprising:
a chamber body having a chamber wall, a chamber plate and a chamber lid, the chamber wall, chamber plate and chamber lid defining a chamber process area;
a wafer support disposed within the chamber process area;
a lifting mechanism positioned within the process chamber that lowers the substrate on to and raises the substrate off the wafer support;
one or more injectors that deliver amine and hydroxide to the chamber process area,
wherein the chamber body, wafer support, lifting mechanism and one or more injectors comprise materials resistant to degradation by ammonium hydroxide; and
a transfer valve disposed in the chamber wall that permits a substrate to be loaded into the process area and out of the process chamber to a transfer chamber adjacent the transfer valve.

15. The apparatus of claim 14, wherein the transfer valve comprises a purge gas injector that flows purge gas when the transfer valve is in an open position.

16. The apparatus of claim 14, wherein the lifting mechanism comprises a peripheral frame engaged with a motor that raises and lowers the frame, and a plurality of ceramic standoffs embedded into the frame that enable point contact of the frame with the substrate.

17. An apparatus to hydroxylate a substrate surface, the apparatus comprising:
a chamber body having a chamber wall, a chamber plate and a chamber lid, the chamber wall, chamber plate and chamber lid defining a chamber process area;
a wafer support disposed within the chamber process area;
a lifting mechanism positioned within the process chamber that lowers the substrate on to and raises the substrate off the wafer support;
one or more injectors that deliver amine and hydroxide into the chamber process area; and
a chamber controller that regulates flow of amine and hydroxide in the chamber and controls the temperature in the chamber to provide a desired relative humidity in the process area to hydroxylate a surface of a substrate when processed in the chamber.

18. The apparatus of claim 17, wherein the chamber body, wafer support, lifting mechanism and one or more injectors comprise materials resistant to degradation by ammonium hydroxide.

19. The apparatus of claim 18, wherein the materials resistant to degradation by ammonium hydroxide comprise one or more of stainless steel, quartz and polytetrafluoroethylene.

20. The apparatus of claim 17, wherein the apparatus further comprises a heating system that maintains temperature adjacent to the chamber lid and chamber wall such that ammonia and water do not react adjacent to the chamber lid and chamber wall and ammonia and water react adjacent to a substrate on the wafer support.
